(19) United States
(12) Patent Application Publication
(10) Pub. No.: US 2022/0183179 A1
(43) Pub. Date: Jun. 9, 2022

(54) HEAT DISSIPATION PLATE

(71) Applicant: Chicony Power Technology Co., Ltd., New Taipei City (TW)

(72) Inventor: Yu-Jan Lin, New Taipei City (TW)

(21) Appl. No.: 17/170,385

(22) Filed: Feb. 8, 2021

(30) Foreign Application Priority Data
Dec. 9, 2020 (TW) 109143531

(51) Int. Cl. H05K 7/20; F28F 9/007

(52) U.S. Cl. CPC H05K 7/205; F28F 2275/143; F28F 9/0075

(57) ABSTRACT

A heat dissipation plate includes a main retaining wall, a left retaining wall, a right retaining wall, and a limiting structure. The main retaining wall has a first side edge, a second side edge, and a third side edge. The left retaining wall and the right retaining wall are respectively connected to the first side edge and the second side edge, and the main retaining wall, the left retaining wall, and the right retaining wall form a U-shaped structure. The limiting structure includes an extension portion and a limiting portion, where the extension portion has a first end and a second end opposite each other, the first end is connected to the third side edge, and the limiting portion is connected to the second end of the extension portion.

### CROSS-REFERENCE TO RELATED APPLICATION

This non-provisional application claims priority under 35 U.S.C. § 119(a) to Patent Application No. 109143531 filed in Taiwan, R.O.C. on Dec. 9, 2020, the entire contents of which are hereby incorporated by reference.

### BACKGROUND

### Technical Field

The instant disclosure relates to a heat dissipation device, and in particular, to a heat dissipation plate.

### Related Art

Heat dissipation plates are widely applied to various products on the market. By contact between the heat dissipation plates and heating elements in various products, heat generated by the heating elements can be transmitted to the heat dissipation plates and then transmitted to an external environment through the heat dissipation plates, to prevent the products from being damaged due to overheating, thereby achieving a heat dissipation effect.

However, currently a heat dissipation plate and a heating element are only in contact with each other during assembly. As a result, the heat dissipation plate and the heating element cannot be tightly attached to each other, thus affecting a heat dissipation effect. In addition, for a plug-in heating element or a stick-on heating element, because there is no limiting structure between the heat dissipation plate and the heating element, the heating element is easily skewed or deviated.

In particular, electronic products are currently designed to be smaller, and heating elements in the electronic products rely on heat dissipation plates for heat dissipation. The conventional design, which is still to be improved, cannot achieve tight attachment and joint location of a heat dissipation plate and a heating element, resulting in a poor heat dissipation effect. In view of this, through dedicated research, a heat dissipation plate in the instant disclosure is developed, to overcome the shortcoming of the conventional technology.

### SUMMARY

A main objective of the instant disclosure is to provide a heat dissipation plate. The heat dissipation plate may be tightly attached to and located together with a heating element, to prevent the heating element from skewing or deviation, and further enhance a heat dissipation effect.

In view of this, a heat dissipation plate is provided in an embodiment, including a main retaining wall, a left retaining wall, a right retaining wall, and a limiting structure. The main retaining wall has a first side edge, a second side edge, and a third side edge. The left retaining wall and the right retaining wall are connected to the first side edge and the second side edge respectively, and the main retaining wall, the left retaining wall, and the right retaining wall form a U-shaped structure. The limiting structure includes an extension portion and a limiting portion, where the extension portion has a first end and a second end opposite to each other, the first end is connected to the third side edge, and the limiting portion is connected to the second end of the extension portion.

A heat dissipation plate is provided in another embodiment, including a main retaining wall, a first limiting structure, and a second limiting structure. The main retaining wall has a first side edge, a second side edge, and a third side edge. The first limiting structure includes a first extension portion and a first limiting portion, where a first end surface of the first extension portion is connected to the first side edge, and the first limiting portion is connected to a first side surface of the first extension portion. The second limiting structure includes a second extension portion and a second limiting portion, where a second end surface of the second extension portion is connected to the second side edge, and the second limiting portion is connected to a second side surface of the second extension portion. The main retaining wall, the first limiting structure, and the second limiting structure form a U-shaped structure, a first distance exists between the main retaining wall and the first limiting portion, and a second distance exists between the main retaining wall and the second limiting portion.

Based on the above, according to the heat dissipation plate in the embodiments of the instant disclosure, through the foregoing structure design, when the main retaining wall of the heat dissipation plate is in contact with a heating element, the heat dissipation plate may secure the heating element in a plurality of directions by using structures (for example, the foregoing left retaining wall, the right retaining wall and the limiting structure, or the first limiting structure and the second limiting structure) extending out from the main retaining wall, and enable the heating element and the heat dissipation plate to be tightly attached, thereby enhancing a heat dissipation effect, and preventing the heating element from skewing, deviation or floating.

### BRIEF DESCRIPTION OF THE DRAWINGS

FIG. 1 is a three-dimensional view of a heat dissipation plate according to a first embodiment of the instant disclosure;

FIG. 2 is a three-dimensional exploded view of the heat dissipation plate in the first embodiment being applied to a circuit board module of an electronic device according to the instant disclosure;

FIG. 3 is a three-dimensional view of the heat dissipation plate in the first embodiment being applied to a circuit board module of an electronic device according to the instant disclosure;

FIG. 4 is a three-dimensional view of a heat dissipation plate according to a second embodiment of the instant disclosure;

FIG. 5 is a three-dimensional exploded view of the heat dissipation plate in the second embodiment being applied to a circuit board module of an electronic device according to the instant disclosure;

FIG. 6 is a three-dimensional view of the heat dissipation plate in the second embodiment being applied to a circuit board module of an electronic device according to the instant disclosure;

FIG. 7 is a three-dimensional view of a heat dissipation plate according to a third embodiment of the instant disclosure;

FIG. 8 is a three-dimensional exploded view of the heat dissipation plate in the third embodiment being applied to a circuit board module of an electronic device according to the instant disclosure;

FIG. 9 is a three-dimensional exploded view of the heat dissipation plate in the third embodiment being applied to a circuit board module of an electronic device according to the instant disclosure;

FIG. 10 is a three-dimensional view of a heat dissipation plate according to a fourth embodiment of the instant disclosure;

FIG. 11 is a three-dimensional exploded view of the heat dissipation plate in the fourth embodiment being applied to a circuit board module of an electronic device according to the instant disclosure;

FIG. 12 is a three-dimensional view of the heat dissipation plate in the fourth embodiment being applied to a circuit board module of an electronic device according to the instant disclosure;

FIG. 13 is a three-dimensional view of a heat dissipation plate according to a fifth embodiment of the instant disclosure;

FIG. 14 is a three-dimensional exploded view of the heat dissipation plate in the fifth embodiment being applied to a circuit board module of an electronic device according to the instant disclosure; and

FIG. 15 is a three-dimensional view of the heat dissipation plate in the fifth embodiment being applied to a circuit board module of an electronic device according to the instant disclosure.

### DETAILED DESCRIPTION

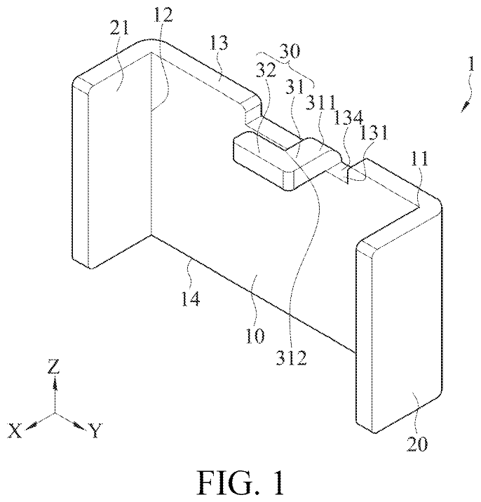

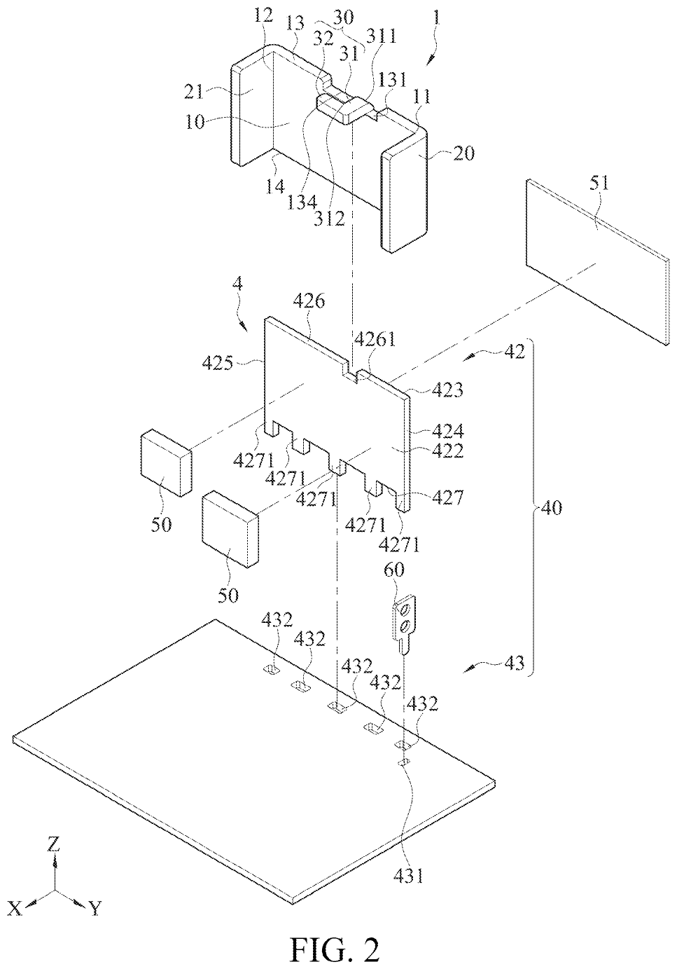

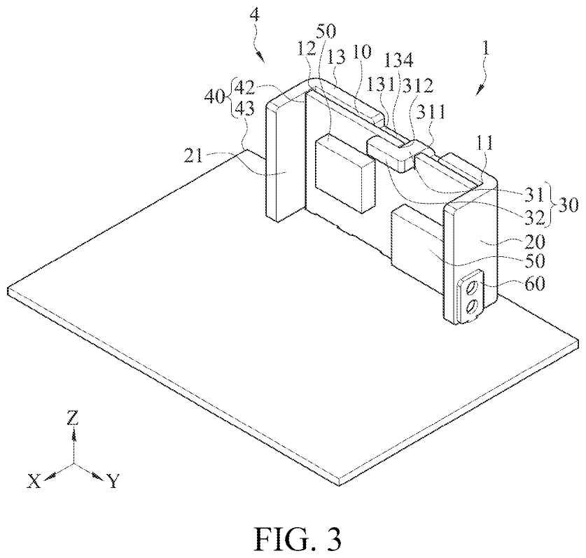

FIG. 1 is a three-dimensional view of a heat dissipation plate according to a first embodiment of the instant disclosure. FIG. 2 is a three-dimensional exploded view of the heat dissipation plate in the first embodiment being applied to a circuit board module of an electronic device according to the instant disclosure. FIG. 3 is a three-dimensional view of the heat dissipation plate in the first embodiment being applied to a circuit board module of an electronic device according to the instant disclosure. As shown in FIG. 1 to FIG. 3, a heat dissipation plate 1 may be widely applied to various products on the market. By contact between the heat dissipation plate 1 and a heating element in such a product, heat generated by the heating element can be transmitted to the heat dissipation plate 1 and then transmitted to an external environment through the heat dissipation plate 1, to prevent the product from being damaged due to overheating, thereby achieving a heat dissipation effect. In some embodiments, the heating element may be, for example, an engine on a car, an electronic part on a computer motherboard, or a circuit board module in an electronic device. The heat dissipation plate 1 has a plurality of embodiments as follows, and descriptions are made with reference to the drawings respectively.

As shown in FIG. 1, in a first embodiment, the heat dissipation plate 1 includes a main retaining wall 10, a left retaining wall 20, a right retaining wall 21, and a limiting structure 30. The main retaining wall 10 has a first side edge 11, a second side edge 12, a third side edge 13, and a fourth side edge 14, where the first side edge 11 and the second side edge 12 are located at opposite sides of the main retaining wall 10 respectively, and the third side edge 13 and the fourth side edge 14 are located at opposite sides of the main retaining wall 10 respectively and are connected between the first side edge 11 and the second side edge 12.

As shown in FIG. 1, the left retaining wall 20 and the right retaining wall 21 are connected to the first side edge 11 and the second side edge 12 respectively, and the main retaining wall 10, the left retaining wall 20, and the right retaining wall 21 form a U-shaped structure. The limiting structure 30 includes an extension portion 31 and a limiting portion 32, where the extension portion 31 has a first end 311 and a second end 312 opposite to each other, the first end 311 is connected to the third side edge 13, and the limiting portion 32 is connected to the second end 312 of the extension portion 31.

Based on the above, as shown in FIG. 1, in this embodiment, the left retaining wall 20 and the right retaining wall 21 of the heat dissipation plate 1 are perpendicular to the main retaining wall 10. The left retaining wall 20 and the right retaining wall 21 respectively extend from the first side edge 11 and the second side edge 12 of the main retaining 10 towards the same direction to form a U-shaped structure. In another implementation, the left retaining wall 20 and the right retaining wall 21 of the heat dissipation plate 1 may not be perpendicular to the main retaining wall 10. For example, an angle between the main retaining wall 10 and the left retaining wall 20 or the right retaining wall 21 may be any angle, which depends on a shape of a heating element to which the heat dissipation plate 1 is applied.

Still as shown in FIG. 1, in this embodiment, the extension portion 31 and the limiting portion 32 of the limiting structure 30 are both boards. The extension portion 31 extends towards the same direction as the left retaining wall 20 and the right retaining wall 21. The limiting portion 32 extends from the second end 312 of the extension portion 31 towards the second side edge 12 of the main retaining wall 10, so that the extension portion 31 and the limiting portion 32 of the limiting structure 30 form an L-shaped structure. In another implementation, the limiting portion 32 of the limiting structure 30 may alternatively extend from the second end 312 of the extension portion 31 towards the first side edge 11 of the main retaining wall 10 to form an L-shaped structure, or the limiting portion 32 may extend from the second end 312 of the extension portion 31 towards the fourth side edge 14 of the main retaining wall 10 to form an L-shaped structure.

Still as shown in FIG. 1, in this embodiment, the extension portion 31 of the limiting structure 30 extends from a middle part 131 of the third side edge 13 of the main retaining wall 10, but this is not limited thereto. In another implementation, the extension portion 31 of the limiting structure 30 may alternatively be adjacent to the first side edge 11 or the second side edge 12. In addition, two or more limiting structures 30 may be provided.

As shown in FIG. 1, the entire heat dissipation plate 1 may be an integrally formed structure. For example, the heat dissipation plate 1 may be formed by integrally bending a metal plate (such as an aluminum plate or a copper plate). In another implementation, the heat dissipation plate 1 may alternatively be a split-piece structure. For example, at least one of the left retaining wall 20, the right retaining wall 21, or the limiting structure 30 of the heat dissipation plate 1 is a split piece. The split piece is secured to the main retaining wall 10 through an assembly method such as adhesion, welding or clamping.

In this way, the heat dissipation plate 1 may secure the heating element in a plurality of directions by using structures (the left retaining wall 20, the right retaining wall 21, and the limiting structure 30) extending out from the main retaining wall 10, and enable the heating element and the heat dissipation plate 1 to be tightly attached.

Based on the above, FIG. 2 and FIG. 3 are a three-dimensional exploded view and a three-dimensional view of the heat dissipation plate in the first embodiment being applied to a circuit board module of an electronic device according to the instant disclosure. An electronic device 4 may be, for example, a smart phone, a notebook computer, a power supply, a transformer, a charger, or the like. The electronic device 4 has a circuit board module 40. The circuit board module 40 includes a first circuit board 42 and a second circuit board 43.

Still as shown in FIG. 2 and FIG. 3, the first circuit board 42 of the circuit board module 40 has a front side surface 422, a rear side surface 423, a left side edge 424, a right side edge 425, a top side edge 426, and a bottom side edge 427. The front side surface 422 and the rear side surface 423 are located at opposite sides of the first circuit board 42 respectively. The left side edge 424 and the right side edge 425 are located at opposite sides of the first circuit board 42 respectively. The top side edge 426 and the bottom side edge 427 are located at other opposite sides of the first circuit board 42 respectively. The left side edge 424, the right side edge 425, the top side edge 426, and the bottom side edge 427 are all connected between the front side surface 422 and the rear side surface 423. The top side edge 426 of the first circuit board 42 has a notch 4261, and the bottom side edge 427 of the first circuit board 42 has at least a pin 4271 (a plurality of pins 4271 herein).

As shown in FIG. 2 and FIG. 3, the second circuit board 43 of the circuit board module 40 has a plurality of insertion holes 432 and a through hole 431. The pins 4271 of the first circuit board 42 is correspondingly inserted in the insertion holes 432 of the second circuit board 43. Then the first circuit board 42 is secured on the second circuit board 43 by wielding, so that circuits of the two circuit boards can be connected to each other.

In addition, both the first circuit board 42 and the second circuit board 43 may be equipped with an electronic part 50. The electronic part 50 is, for example, a plug-in electronic part, a stick-on electronic part, an integrated circuit, a transistor, a resistor, or the like. In this embodiment, the electronic part 50 is a stick-on electronic part, to increase a density of the electronic parts 50 in the circuit board module 40, and further miniaturize the electronic device 4.

Still as shown in FIG. 2 and FIG. 3, the heat dissipation plate 1 further includes a securing portion 60. The securing portion 60 is disposed at a lower side of the left retaining wall 20 or the right retaining wall 21. The securing portion 60 herein is a rivet, and may be secured at a lower side of the left retaining wall 20 in a manner of locking, riveting, sticking, or the like. Then the securing portion 60 of the heat dissipation plate 1 passes through and is secured at the through hole 431 of the second circuit board 43 through riveting, so that the heat dissipation plate 1 can be secured on the second circuit board 43. In this embodiment, the securing portion 60 and the heat dissipation plate 1 may alternatively be integrally formed.

As shown in FIG. 2 and FIG. 3, the extension portion 31 of the limiting structure 30 of the heat dissipation plate 1 correspondingly passes through the notch 4261 of the first circuit board 42, and presses against the top side edge 426 of the first circuit board 42. In this way, the position of the first circuit board 42 is limited by the heat dissipation plate 1 in an up-down direction (Z axis direction herein), thereby avoiding skewing and floating of the first circuit board 42. In addition, the extension portion 31 of the limiting structure 30 passes through the notch 4261. Therefore, the heat dissipation plate 1 and the first circuit board 42 can further restrict each other and thus be limited in a left-right direction (Y axis direction herein).

Based on the above, as shown in FIG. 2 and FIG. 3, the limiting portion 32 of the limiting structure 30 and the main retaining wall 10 of the heat dissipation plate 1 press against the front side surface 422 and the rear side surface 423 of the first circuit board 42 respectively, so that the heat dissipation plate 1 and the first circuit board 42 can restrict each other in a front-rear direction (X axis direction herein), to achieve tight attachment and improve a heat dissipation effect. In addition, the left retaining wall 20 and the right retaining wall 21 of the heat dissipation plate 1 press against the left side edge 424 and the right side edge 425 of the first circuit board 42 respectively, so that the first circuit board 42 is further limited in the left-right direction (Y axis direction herein) by the heat dissipation plate 1, thereby avoiding deviation of the first circuit board 42.

Based on the above, when the main retaining wall 10 of the heat dissipation plate 1 is in contact with the first circuit board 42, the first circuit board 42 can be secured in a plurality of directions by using the main retaining wall 10, the left retaining wall 20, the right retaining wall 21, and the limiting structure 30 and can be tightly attached to the heat dissipation plate 1, to improve a heat dissipation effect and avoid skewing, deviation, or floating of the first circuit board 42.

Based on the above, as shown in FIG. 2, a heat conducting gasket 51, for example, a thermal conductive silicone or thermal paste, may be adhered between the main retaining wall 10 of the heat dissipation plate 1 and the rear side surface 423 of the first circuit board 42, to improve the heat dissipation effect. In another implementation, the circuit board module 40 of the electronic device 4 may include only one circuit board, for example, the first circuit board 42.

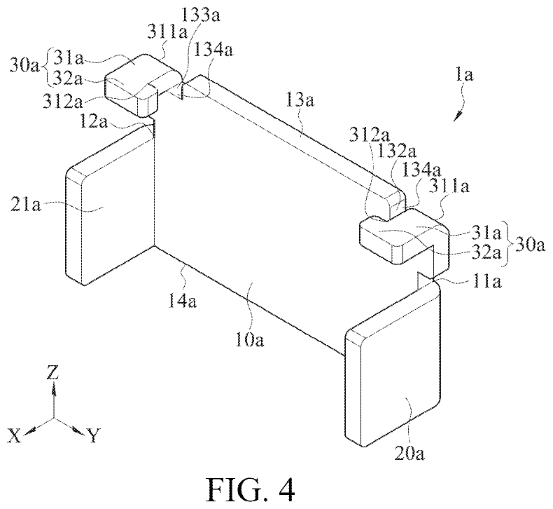

FIG. 4 is a three-dimensional view of a heat dissipation plate according to a second embodiment of the instant disclosure. As shown in FIG. 4, in the second embodiment, a heat dissipation plate 1a includes a main retaining wall 10a, a left retaining wall 20a, a right retaining wall 21a, and two limiting structures 30a. The main retaining wall 10a has a first side edge 11a, a second side edge 12a, a third side edge 13a, and a fourth side edge 14a, where the first side edge 11a and the second side edge 12a are located at opposite sides of the main retaining wall 10a respectively, and the third side edge 13a and the fourth side edge 14a are located at opposite sides of the main retaining wall 10a respectively and are connected between the first side edge 11a and the second side edge 12a. A left end 132a and a right end 133a of the third side edge 13a are adjacent to the first side edge 11a and the second side edge 12a respectively.

As shown in FIG. 4, the left retaining wall 20a and the right retaining wall 21a are connected to the first side edge 11a and the second side edge 12a respectively, and the main retaining wall 10a, the left retaining wall 20a, and the right retaining wall 21a form a U-shaped structure. Each limiting structure 30a includes an extension portion 31a and a limiting portion 32a. Each extension portion 31a has a first end 311a and a second end 312a opposite to each other. Each first end 311a is connected to the left end 132a and the right end 133a of the third side edge 13a, and the limiting portions 32a are connected to the second ends 312a of the extension portions 31a respectively.

Based on the above, as shown in FIG. 4, in this embodiment, the left retaining wall 20a and the right retaining wall 21a of the heat dissipation plate 1a are perpendicular to the main retaining wall 10a. The left retaining wall 20a and the right retaining wall 21a respectively extend from the first side edge 11a and the second side edge 12a of the main retaining wall 10a towards the same direction, to form the foregoing U-shaped structure.

Still as shown in FIG. 4, the limiting portions 32a of the limiting structures 30a may extend towards the same direction or towards different directions. In this embodiment, the extension portion 31a and the limiting portion 32a of each limiting structure 30a are both boards. Each extension portion 31a extends toward the same direction as the left retaining wall 20a and the right retaining wall 21a, and the limiting portion 32a adjacent to the left end 132a extends from the second end 312a of the extension portion 31a towards the second side edge 12a of the main retaining wall 10a. The limiting portion 32a adjacent to the right end 133a extends from the second end 312a of the extension portion 31a towards the first side edge 11a of the main retaining wall 10a. In this way, the extension portions 31a and the limiting portions 32a of the limiting structures 30a form two symmetric L-shaped structures facing each other. In another implementation, the two limiting structures 30a have various possible arrangement manners. The limiting portion 32a of one limiting structure 30a may extend from the second end 312a of the extension portion 31a towards the first side edge 11a, the second side edge 12a, or the fourth side edge 14a of the main retaining wall 10a. The limiting portion 32a of the other limiting structure 30a may also extend from the second end 312a of the extension portion 31a towards the first side edge 11a, the second side edge 12a, or the fourth side edge 14a of the main retaining wall 10a.

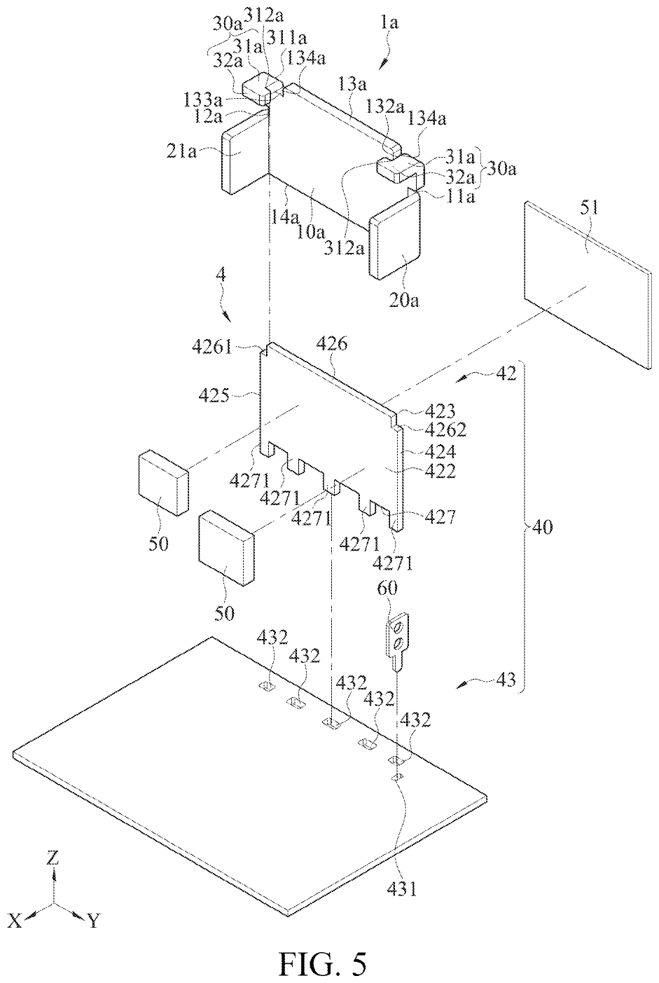

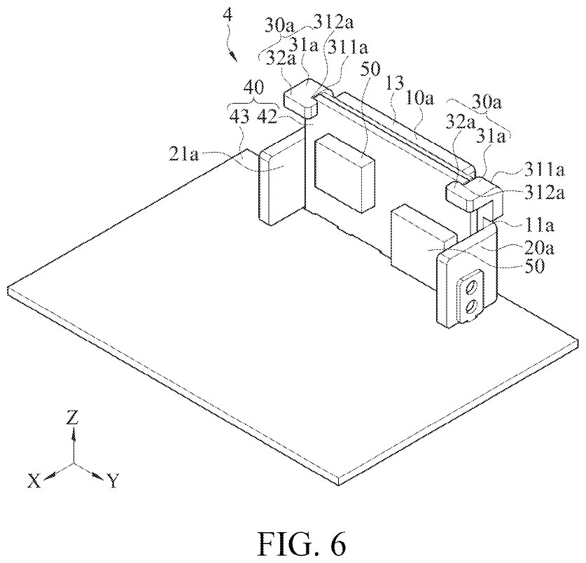

Based on the above, FIG. 5 and FIG. 6 are a three-dimensional exploded view and a three-dimensional view of the heat dissipation plate in the second embodiment being applied to a circuit board module of an electronic device according to the instant disclosure. A top side edge 426 of a first circuit board 42 is provided with a notch 4262 adjacent to a left side edge 424 and a notch 4262 adjacent to a right side edge 425. The extension portions 31a of the limiting structures 30a of the heat dissipation plate 1a correspondingly pass through the notches 4262 of the first circuit board 42, and press against the top side edge 426 of the first circuit board 42. In this way, the first circuit board 42 is limited in an up-down direction (Z axis direction herein) by the heat dissipation plate 1a, thereby avoiding skewing or floating of the first circuit board 42. In addition, the extension portions 31a of the limiting structures 30a pass through the notches 4262. Therefore, the heat dissipation plate 1a and the first circuit board 42 can further restrict each other and thus be limited in a left-right direction (Y axis direction herein).

Based on the above, as shown in FIG. 5 and FIG. 6, the limiting portion 32a of each limiting structure 30a of the heat dissipation plate 1a presses against a front side surface 422 of the first circuit board 42, and the main retaining wall 10a of the heat dissipation plate 1a presses against a rear side surface 423 of the first circuit board 42, so that the heat dissipation plate 1a and the first circuit board 42 can restrict each other in a front-rear direction (X axis direction herein), to achieve tight attachment and improve a heat dissipation effect. In addition, the left retaining wall 20a and the right retaining wall 21a of the heat dissipation plate 1a press against a left side edge 424 and a right side edge 425 of the first circuit board 42 respectively, so that the first circuit board 42 is further limited in the left-right direction (Y axis direction herein) by the heat dissipation plate 1a, thereby avoiding deviation of the first circuit board 42.

In addition, because the extension portions 31a and the limiting portions 32a of the limiting structures 30a form two L-shaped structures that press against the first circuit board 42, restraining force between the heat dissipation plate 1a and the first circuit board 42 can be uniformly distributed. The extension portions 31a are located at the left end 132a and the right end 133a of the third side edge 13a respectively. Therefore, the restriction between the heat dissipation plate 1a and the first circuit board 42 can be more stable. In this way, in addition to improving the heat dissipation effect, the heat dissipation plate 1a can also avoid stress concentration on the first circuit board 42, thereby further increasing product availability.

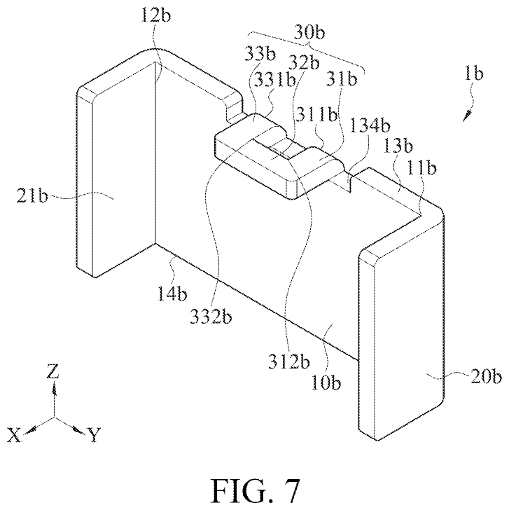

FIG. 7 is a three-dimensional view of a heat dissipation plate according to a third embodiment of the instant disclosure. As shown in FIG. 7, in the third embodiment, a heat dissipation plate 1b includes a main retaining wall 10b, a left retaining wall 20b, a right retaining wall 21b, and a limiting structure 30b. The main retaining wall 10b has a first side edge 11b, a second side edge 12b, a third side edge 13b, and a fourth side edge 14b, where the first side edge 11b and the second side edge 12b are located at opposite sides of the main retaining wall 10b respectively, and the third side edge 13b and the fourth side edge 14b are located at opposite sides of the main retaining wall 10b respectively and are connected between the first side edge 11b and the second side edge 12b.

As shown in FIG. 7, the left retaining wall 20b and the right retaining wall 21b are connected to the first side edge 11b and the second side edge 12b respectively, and the main retaining wall 10b, the left retaining wall 20b, and the right retaining wall 21b form a U-shaped structure. The limiting structure 30b includes an extension portion 31b and a limiting portion 32b, where the extension portion 31b has a first end 311b and a second end 312b opposite to each other, the first end 311b is connected to the third side edge 13b, and the limiting portion 32b is connected to the second end 312b of the extension portion 31b.

Still as shown in FIG. 7, in this embodiment, the limiting structure 30b of the heat dissipation plate 1b further includes another extension portion 33b. The another extension portion 33b has a third end 331b and a fourth end 332b opposite to each other. The third end 331b is connected to the third side edge 13b, and the limiting portion 32b is connected between the second end 312b of the extension portion 31b and the fourth end 332b of the another extension portion 33b.

As shown in FIG. 7, in this embodiment, the left retaining wall 20b and the right retaining wall 21b of the heat dissipation plate 1b are perpendicular to the main retaining wall 10b. The left retaining wall 20b and the right retaining wall 21b respectively extend from the first side edge 11b and the second side edge 12b of the main retaining wall 10b towards the same direction.

Still as shown in FIG. 7, in this embodiment, the extension portions 31b and 33b, and the limiting portion 32b of the limiting structure 30 are boards. The extension portions 31b and 33b, the left retaining wall 20b, and the right retaining wall 21b extend towards the same direction. The limiting portion 32b extends from the second end 312b of the extension portion 31b towards the second side edge 12b of the main retaining wall 10b to reach the fourth end 332b of the another extension portion 33b, so that the extension portions 31b and 33b and the limiting portion 32b of the limiting structure 30b form a U-shaped structure.

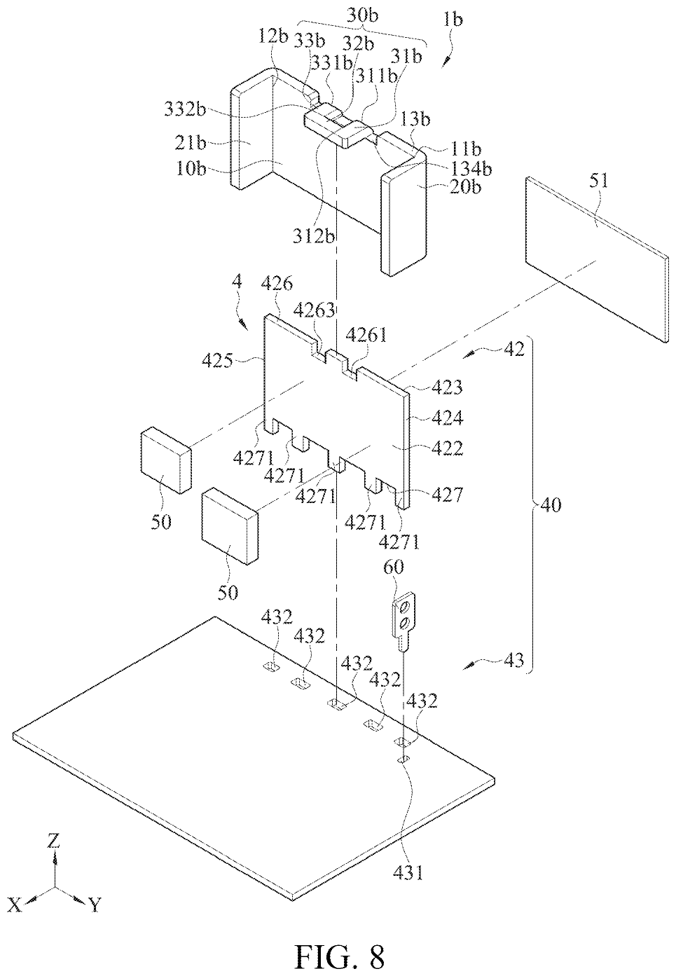

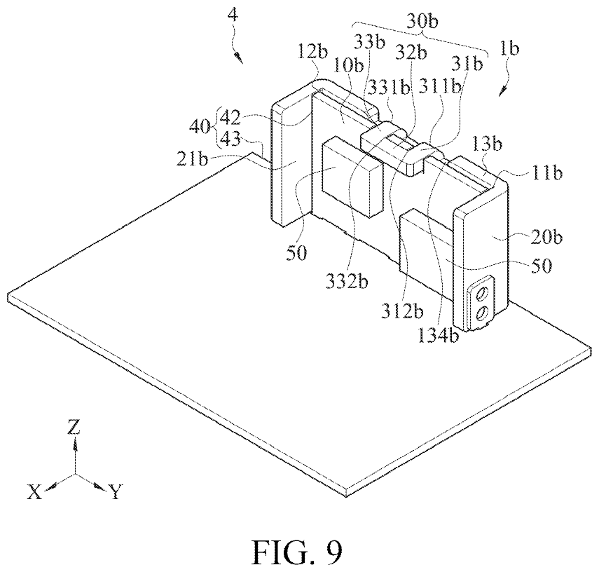

FIG. 8 and FIG. 9 are a three-dimensional exploded view and a three-dimensional view of the heat dissipation plate in the third embodiment being applied to a circuit board module of an electronic device according to the instant disclosure. A top side edge 426 of a first circuit board 42 is provided with notches 4261 and 4263 adjacent to a middle position. The extension portions 31b and 33b of the limiting structure 30b of the heat dissipation plate 1b correspondingly pass through the notches 4261 and 4263 of the first circuit board 42 respectively, and press against the top side edge 426 of the first circuit board 42. In this way, the first circuit board 42 is limited in an up-down direction (Z axis direction herein) by the heat dissipation plate 1b, thereby avoiding skewing or floating of the first circuit board 42. In addition, the extension portion 31b of each limiting structure 30b passes through each notch 4261. Therefore, the heat dissipation plate 1b and the first circuit board 42 can further restrict each other and thus be limited in a left-right direction (Y axis direction herein).

Based on the above, as shown in FIG. 8 and FIG. 9, the limiting portion 32b of the limiting structure 30b and the main retaining wall 10b of the heat dissipation plate 1b press against a front side surface 422 and a rear side surface 423 of the first circuit board 42 respectively, so that the heat dissipation plate 1b and the first circuit board 42 can restrict each other in a front-rear direction (X axis direction herein), to achieve tight attachment and improve a heat dissipation effect. In addition, the left retaining wall 20b and the right retaining wall 21b of the heat dissipation plate 1b press against a left side edge 424 and a right side edge 425 of the first circuit board 42 respectively, so that the first circuit board 42 is further limited in the left-right direction (Y axis direction herein) by the heat dissipation plate 1b, thereby avoiding deviation of the first circuit board 42.

In addition, because the extension portion 31b and the another extension portion 33b of the limiting structure 30b press against the first circuit board 42, restraining force between the heat dissipation plate 1b and the first circuit board 42 can be uniformly distributed. In this way, stress concentration on the first circuit board 42 can be avoided, and overall product availability can further be increased.

As shown in FIG. 1, FIG. 4, and FIG. 7, from the first embodiment to the third embodiment, the left retaining walls 20, 20a, and 20b, the right retaining walls 21, 21a, and 21b, and the extension portions 31, 31a, 31b, and 33b of the heat dissipation plates 1, 1a, and 1b all extend from the main retaining walls 10, 10a, and 10b towards the same direction. Therefore, the heat dissipation plates 1, 1a, and 1b can be manufactured with one metal stamping process, thereby reducing product manufacturing costs.

Still as shown in FIG. 1, FIG. 4, and FIG. 7, from the first embodiment to the third embodiment, the third side edges 13, 13a, and 13b of the main retaining walls 10, 10a, 10b have concave portions 134, 134a, and 134b. As shown in FIG. 1 and FIG. 4, in the first embodiment and the second embodiment, the first ends 311 and 311a of the extension portions 31 and 31a are connected to bottom surfaces of the concave portions 134 and 134a. The extension portions 31 and 31a and the limiting portions 32 and 32a form L-shaped structures.

Still as shown in FIG. 7, in the third embodiment, the limiting structure 30b further includes another extension portion 33b, and the another extension portion 33b has a third end 331b and a fourth end 332b opposite to each other. The first end 311b of the extension portion 31b and the third end 331b of the another extension portion 33b are connected to a bottom surface of a concave portion 134b, and the limiting portion 32b is connected between the second end 312b of the extension portion 31b and the fourth end 332b of the another extension portion 33b.

Based on the above, because the third side edges 13, 13a, and 13b of the main retaining walls 10, 10a, and 10b have concave portions, during manufacturing of the heat dissipation plates 1, 1a, and 1b through metal stamping, the extension portions 31, 31a, 31b, and 33b of the limiting structures 30, 30a, and 30b can be formed through bending more smoothly, thereby improving a product manufacturing yield.

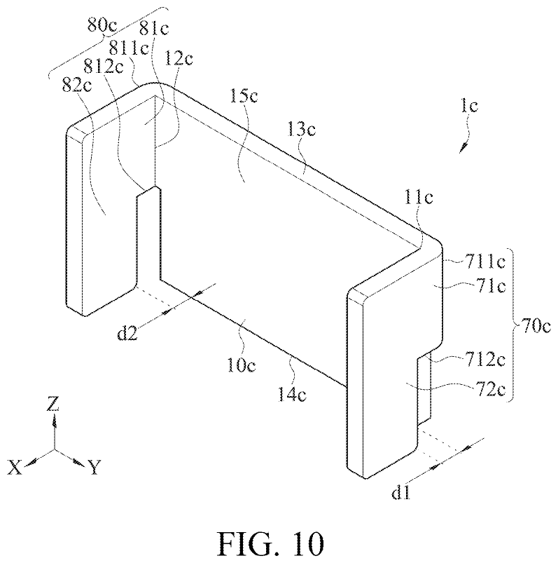

FIG. 10 is a three-dimensional view of a heat dissipation plate according to a fourth embodiment of the instant disclosure. As shown in FIG. 10, in the fourth embodiment, a heat dissipation plate 1c includes a main retaining wall 10c, a first limiting structure 70c, and a second limiting structure 80c. The main retaining wall 10c has a first side edge 11c, a second side edge 12c, a third side edge 13c, a fourth side edge 14c, and a front plane 15c, where the first side edge 11c and the second side edge 12c are located at opposite sides of the main retaining wall 10c respectively, and the third side edge 13c and the fourth side edge 14c are located at opposite sides of the main retaining wall 10c respectively and are connected between the first side edge 11c and the second side edge 12c.

As shown in FIG. 10, the first limiting structure 70c includes a first extension portion 71c and a first limiting portion 72c, where a first end surface 711c of the first extension portion 71c is connected to the first side edge 11c, and the first limiting portion 72c is connected to a first side surface 712c of the first extension portion 71c. The second limiting structure 80c includes a second extension portion 81c and a second limiting portion 82c, where a second end surface 811c of the second extension portion 81c is connected to the second side edge 12c, and the second limiting portion 82c is connected to a second side surface 812c of the second extension portion 81c. The main retaining wall 10c, the first limiting structure 70c, and the second limiting structure 80c form a U-shaped structure.

Based on the above, as shown in FIG. 10, in this embodiment, the first limiting structure 70c and the second limiting structure 80c of the heat dissipation plate 1c are perpendicular to the main retaining wall 10c. The first extension portion 71c of the first limiting structure 70c and the second extension portion 81c of the second limiting structure 80c respectively extend from areas, which are adjacent to the third side edge 13c, of the first side edge 11c and the second side edge 12c of the main retaining wall 10c towards the same direction. The first limiting portion 72c of the first limiting structure 70c and the second limiting portion 82c of the second limiting structure 80c extend towards the same direction as the first extension portion 71c and the second extension portion 81c to form the foregoing U-shaped structure.

Based on the above, as shown in FIG. 10, the first extension portion 71c is connected between a partial area of the first side edge 11c of the main retaining wall 10c and a partial area of the first limiting portion 72c. The second extension portion 81c is connected between a partial area of the second side edge 12c of the main retaining wall 10c and a partial area of the second limiting portion 82c. A first distance d1 exists between the first limiting portion 72c and the front plane 15c of the main retaining wall 10c, and a second distance d2 exists between the second limiting portion 82c and the front plane 15c of the main retaining wall 10c.

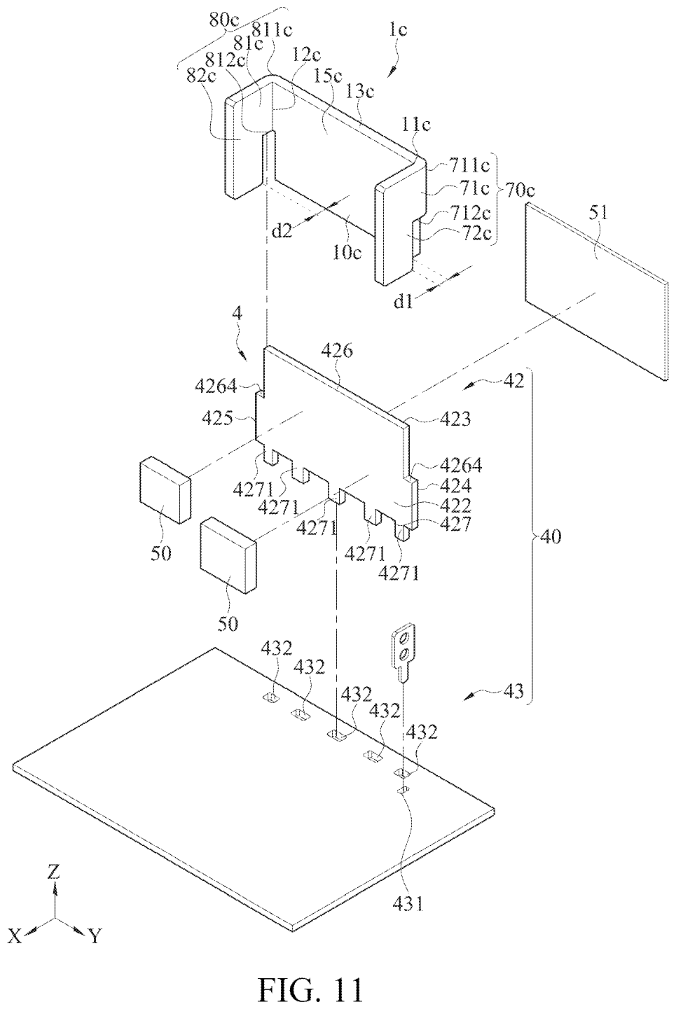

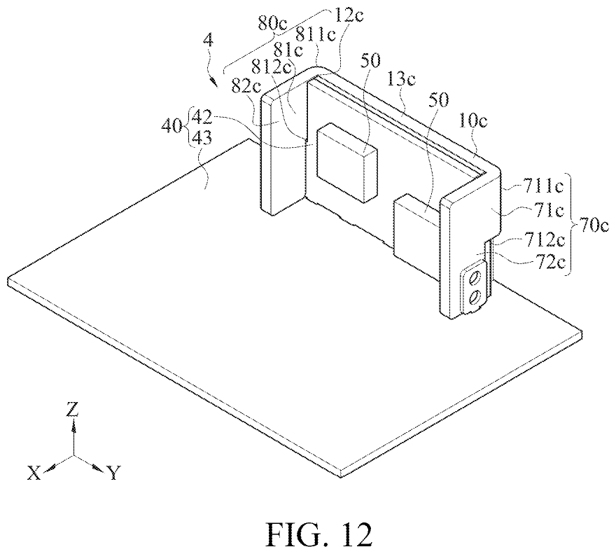

FIG. 11 and FIG. 12 are a three-dimensional exploded view and a three-dimensional view of the heat dissipation plate in the fourth embodiment being applied to a circuit board module of an electronic device according to the instant disclosure. A top side edge 426 of a first circuit board 42 is provided with two notches 4264 that are adjacent to a left side edge 424 and a right side edge 425 respectively. The first extension portion 71c of the first limiting structure 70c of the heat dissipation plate 1c and the second extension portion 81c of the second limiting structure 80c correspondingly pass through the notches 4264 of the first circuit board 42 respectively, and press against the top side edge 426 of the first circuit board 42. In this way, the first circuit board 42 is limited in an up-down direction (Z axis direction herein) by the heat dissipation plate 1c, thereby avoiding skewing or floating of the first circuit board 42.

Based on the above, as shown in FIG. 11 and FIG. 12, the first limiting portion 72c of the first limiting structure 70c and the second limiting portion 82c of the second limiting structure 80c of the heat dissipation plate 1c press against a front side surface 422 of the first circuit board 42, and the main retaining wall 10c of the heat dissipation plate 1c presses against a rear side surface 423 of the first circuit board 42, so that the heat dissipation plate 1c and the first circuit board 42 can restrict each other in a front-rear direction (X axis direction herein), to achieve tight attachment and improve a heat dissipation effect. In addition, the first extension portion 71c of the first limiting structure 70c and the second extension portion 81c of the second limiting structure 80c of the heat dissipation plate 1c press against a left side edge 424 and a right side edge 425 of the first circuit board 42 respectively, so that the heat dissipation plate 1c and the first circuit board 42 can restrict each other in a left-right direction (Y axis direction herein), thereby avoiding deviation of the first circuit board 42.

Based on the above, when the main retaining wall 10c of the heat dissipation plate 1c is in contact with the first circuit board 42, the first circuit board 42 can be secured in a plurality of directions by using the main retaining wall 10c, the first limiting structure 70c, and the second limiting structure 80c and can be tightly attached to the heat dissipation plate 1c, to improve a heat dissipation effect and avoid skewing, deviation or floating of the first circuit board 42.

In addition, because the first limiting structure 70c and the second limiting structure 80c correspondingly press against the first circuit board 42, restraining force between the heat dissipation plate 1c and the first circuit board 42 can be uniformly distributed. In addition, the first limiting structure 70c and the second limiting structure 80c are located at the first side edge 11c and the second side edge 12c respectively. Therefore, the restriction between the heat dissipation plate 1c and the first circuit board 42 can be more stable. In this way, in addition to improving a heat dissipation effect, the heat dissipation plate 1c can also avoid stress concentration on the first circuit board 42, thereby increasing product availability.

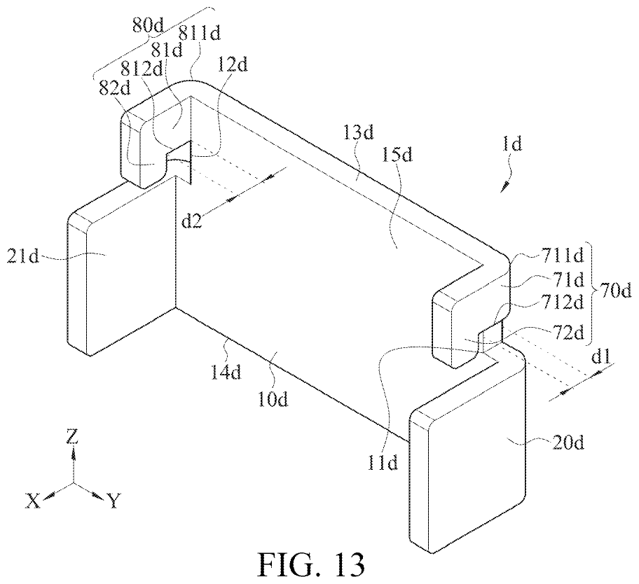

FIG. 13 is a three-dimensional view of a heat dissipation plate according to a fifth embodiment of the instant disclosure. As shown in FIG. 13, in the fifth embodiment, the heat dissipation plate 1d includes a main retaining wall 10d, a first limiting structure 70d, and a second limiting structure 80d. The main retaining wall 10d has a first side edge 11d, a second side edge 12d, a third side edge 13d, a fourth side edge 14d, and a front plane 15d, where the first side edge 11d and the second side edge 12d are located at opposite sides of the main retaining wall 10d respectively, and the third side edge 13d and the fourth side edge 14d are located at opposite sides of the main retaining wall 10d respectively and are connected between the first side edge 11d and the second side edge 12d.

As shown in FIG. 13, the first limiting structure 70d includes a first extension portion 71d and a first limiting portion 72d, where a first end surface 711d of the first extension portion 71d is connected to the first side edge 11d, and the first limiting portion 72d is connected to a first side surface 712d of the first extension portion 71d. The second limiting structure 80d includes a second extension portion 81d and a second limiting portion 82d, where a second end surface 811d of the second extension portion 81d is connected to the second side edge 12d, and the second limiting portion 82d is connected to a second side surface 812d of the second extension portion 81d. The main retaining wall 10d, the first limiting structure 70d, and the second limiting structure 80d form a U-shaped structure.

Based on the above, as shown in FIG. 13, in this embodiment, the first limiting structure 70d and the second limiting structure 80d of the heat dissipation plate 1d are perpendicular to the main retaining wall 10d. The first extension portion 71d of the first limiting structure 70d and the second extension portion 81d of the second limiting structure 80d respectively extend from areas, which are adjacent to the third side edge 13d, of the first side edge 11d and the second side edge 12d of the main retaining wall 10d towards the same direction. The first limiting portion 72d of the first limiting structure 70d and the second limiting portion 82d of the second limiting structure 80d extend towards the same direction as the first extension portion 71d and the second extension portion 81d to form the foregoing U-shaped structure.

Based on the above, as shown in FIG. 13, the first extension portion 71d is connected between a partial area of the first side edge 11d of the main retaining wall 10d and a partial area of the first limiting portion 72d. The second extension portion 81d is connected between a partial area of the second side edge 12d of the main retaining wall 10d and a partial area of the second limiting portion 82d. A first distance d1 exists between the first limiting portion 72d and the front plane 15d of the main retaining wall 10d, and a second distance d2 exists between the second limiting portion 82d and the front plane 15d of the main retaining wall 10d.

As shown in FIG. 13, the heat dissipation plate 1d further includes a left retaining wall 20d and a right retaining wall 21d. The left retaining wall 20d and the right retaining wall 21d are connected to the first side edge 11d and the second side edge 12d respectively, where the main retaining wall 10d, the left retaining wall 20d, and the right retaining wall 21d form a U-shaped structure. In this embodiment, the left retaining wall 20d and the right retaining wall 21d of the heat dissipation plate 1d are perpendicular to the main retaining wall 10d. The left retaining wall 20d and the right retaining wall 21d respectively extend from the first side edge 11d and the second side edge 12d of the main retaining wall 10d towards the same direction.

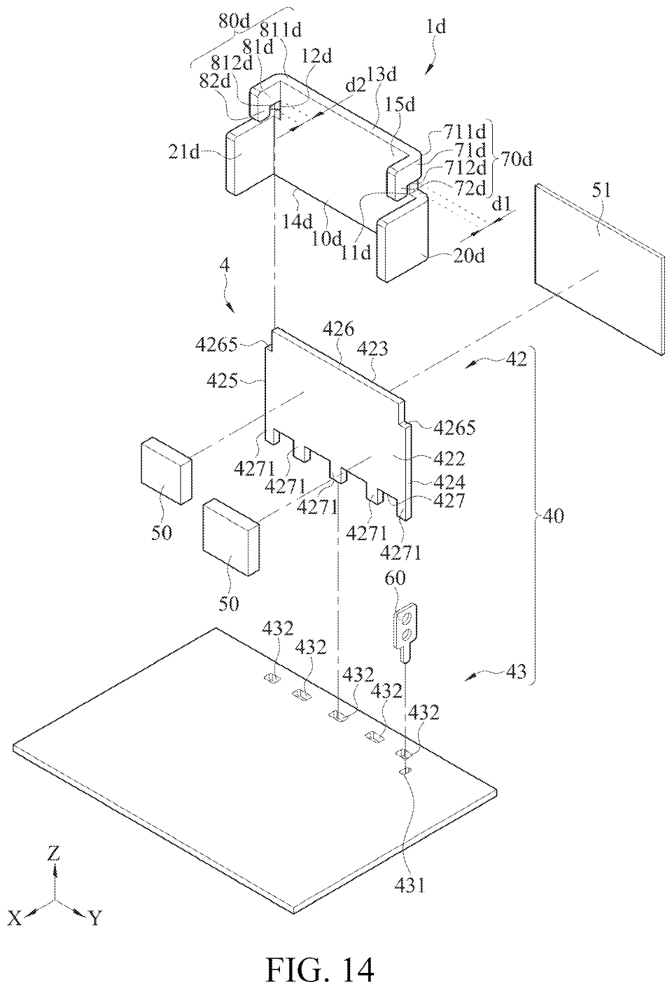

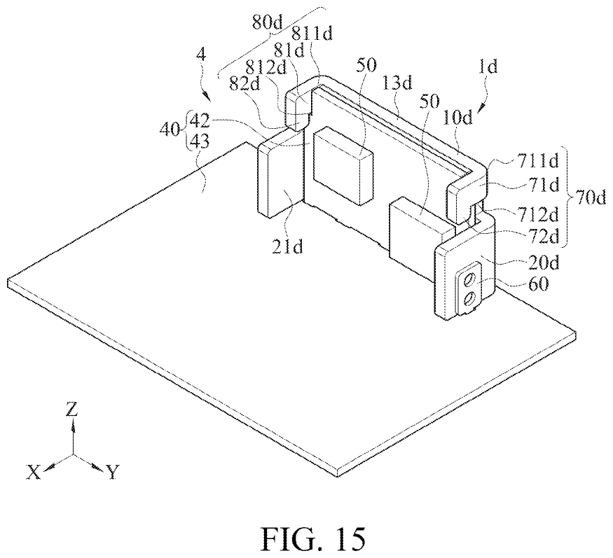

FIG. 14 and FIG. 15 are a three-dimensional exploded view and a three-dimensional view of the heat dissipation plate in the fifth embodiment being applied to a circuit board module of an electronic device according to the instant disclosure. A top side edge 426 of a first circuit board 42 is provided with two notches 4265 that are adjacent to a left side edge 424 and a right side edge 425 respectively. The first extension portion 71d of the first limiting structure 70d and the second extension portion 81d of the second limiting structure 80d of the heat dissipation plate 1d correspondingly pass through the notches 4265 of the first circuit board 42 respectively, and press against the top side edge 426 of the first circuit board 42. In this way, the first circuit board 42 is limited in an up-down direction (Z axis direction herein) by the heat dissipation plate 1d, thereby avoiding skewing or floating of the first circuit board 42.

Based on the above, as shown in FIG. 13 and FIG. 14, the first limiting portion 72d of the first limiting structure 70d and the second limiting portion 82d of the second limiting structure 80d of the heat dissipation plate 1d press against a front side surface 422 of the first circuit board 42, and the main retaining wall 10d of the heat dissipation plate 1d presses against a rear side surface 423 of the first circuit board 42, so that the heat dissipation plate 1d and the first circuit board 42 can restrict each other in a front-rear direction (X axis direction herein), to achieve tight attachment and improve a heat dissipation effect. In addition, the first extension portion 71d of the first limiting structure 70d and the left retaining wall 20d of the heat dissipation plate 1d press against a left side edge 424 of the first circuit board 42, and the second extension portion 81d of the second limiting structure 80d and the right retaining wall 21d of the heat dissipation plate 1d press against a right side edge 425 of the first circuit board 42, so that the heat dissipation plate 1d and the first circuit board 42 can restrict each other in a left-right direction (Y axis direction herein), thereby avoiding deviation of the first circuit board 42.

In addition, the first extension portion 71d of the first limiting structure 70d and the left retaining wall 20d press against the left side edge 424 of the first circuit board 42, and the second extension portion 81d of the second limiting structure 80d and the right retaining wall 21d press against the right side edge 425 of the first circuit board 42, so that restraining force between the heat dissipation plate 1d and the first circuit board 42 can be uniformly distributed. In addition, the first limiting structure 70d and the left retaining wall 20d are located at the first side edge 11d, and the second limiting structure 80d and the right retaining wall 21d are located at the second side edge 12d. Therefore, the restriction between the heat dissipation plate 1d and the first circuit board 42 can be more stable.

Although the instant disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A heat dissipation plate, comprising:
a main retaining wall, having a first side edge, a second side edge, and a third side edge;
a left retaining wall and a right retaining wall, wherein the left retaining wall and the right retaining wall are connected to the first side edge and the second side edge respectively, and the main retaining wall, the left retaining wall, and the right retaining wall form a U-shaped structure; and
a limiting structure, comprising an extension portion and a limiting portion, wherein the extension portion has a first end and a second end opposite to each other, the first end is connected to the third side edge, and the limiting portion is connected to the second end of the extension portion.

2. The heat dissipation plate according to claim 1, wherein the extension portion and the limiting portion form an L-shaped structure.

3. The heat dissipation plate according to claim 1, wherein the limiting structure further comprises another extension portion, the another extension portion has a third end and a fourth end opposite to each other, the third end is connected to the third side edge, and the limiting portion is connected between the second end of the extension portion and the fourth end of the another extension portion.

4. The heat dissipation plate according to claim 1, wherein the third side edge has a concave portion.

5. The heat dissipation plate according to claim 4, wherein the first end of the extension portion is connected to a bottom surface of the concave portion, and the extension portion and the limiting portion form an L-shaped structure.

6. The heat dissipation plate according to claim 4, wherein the limiting structure further comprises another extension portion, the another extension portion has a third end and a fourth end opposite to each other, the first end of the extension portion and the third end of the another extension portion are connected to a bottom surface of the concave portion, and the limiting portion is connected between the second end of the extension portion and the fourth end of the another extension portion.

7. The heat dissipation plate according to claim 1, further comprising a securing portion, wherein the securing portion is disposed at a lower side of the left retaining wall or the right retaining wall.

8. A heat dissipation plate, comprising:
a main retaining wall, having a first side edge, a second side edge, and a third side edge;
a first limiting structure, comprising a first extension portion and a first limiting portion, wherein a first end surface of the first extension portion is connected to the first side edge, and the first limiting portion is connected to a first side surface of the first extension portion; and
a second limiting structure, comprising a second extension portion and a second limiting portion, wherein a second end surface of the second extension portion is connected to the second side edge, and the second limiting portion is connected to a second side surface of the second extension portion,
wherein the main retaining wall, the first limiting structure, and the second limiting structure form a U-shaped structure, a first distance exists between the main retaining wall and the first limiting portion, and a second distance exists between the main retaining wall and the second limiting portion.

9. The heat dissipation plate according to claim 8, further comprising a left retaining wall and a right retaining wall, wherein the left retaining wall and the right retaining wall are connected to the first side edge and the second side edge respectively, and the main retaining wall, the left retaining wall, and the right retaining wall form a U-shaped structure.

10. The heat dissipation plate according to claim 9, further comprising a securing portion, wherein the securing portion is disposed at a lower side of the left retaining wall or the right retaining wall.
